(19) United States
(12) Patent Application Publication
(10) Pub. No.: US 2025/0118357 A1
(43) Pub. Date: Apr. 10, 2025

(54) SEMICONDUCTOR DEVICE

(71) Applicant: Electronics and Telecommunications Research Institute, Daejeon (KR)

(72) Inventors: Sooji NAM, Daejeon (KR); Sung Haeng CHO, Daejeon (KR); Jeho NA, Daejeon (KR); Chihun SUNG, Daejeon (KR); Kyunghee CHOI, Daejeon (KR); Jung Hoon HAN, Daejeon (KR)

(21) Appl. No.: 18/892,187

(22) Filed: Sep. 20, 2024

(30) Foreign Application Priority Data
Oct. 6, 2023 (KR) 10-2023-0133562
Jul. 18, 2024 (KR) 10-2024-0094932

(51) Int. Cl. G11C 11/4096; H10B 12/00

(52) U.S. Cl. CPC G11C 11/4096; H10B 12/33

(57) ABSTRACT

Provided is a semiconductor device including a substrate, a first transistor on the substrate, an interlayer insulating layer covering the first transistor, a second transistor on the interlayer insulating layer, and a storage node contact passing through the interlayer insulating layer, and connecting any one of source/drain electrodes of the first transistor and a gate electrode of the second transistor, wherein a first channel pattern of the first transistor may include an n-type oxide transistor, and a second channel pattern of the second transistor may include an p-type oxide transistor.

### CROSS-REFERENCE TO RELATED APPLICATIONS

This U.S. non-provisional patent application claims priority under 35 U.S.C. § 119 of Korean Patent Application Nos. 10-2023-0133562, filed on Oct. 6, 2023, and 10-2024-0094932, filed on Jul. 18, 2024, the entire contents of which are hereby incorporated by reference.

### BACKGROUND

The present disclosure herein relates to a semiconductor device, and more particularly, to a semiconductor device including a vertically-stacked memory cell transistor based on an oxide semiconductor and an operating method thereof.

In order to implement a data-centric computing technology, such as big data and artificial intelligence, it is necessary to improve the degree of integration of a memory for implementing a large-capacity memory, and also, to improve data transfer performance required to access the memory to read and write data, and in addition, it is essential to reduce power consumption associated therewith.

However, the current Dynamic Random Access Memory (DRAM) structure, which is represented by a typical Si semiconductor-based 1T-1C structure, is stagnant in performance improvement due to the trade-off relationship between an increase in leakage current caused by miniaturization and an increase in accumulated capacity to overcome the increase in leakage current. As a result, memory transfer performance relative to CPU processing speed, which is represented by the integration capability of a transistor, remains low, and a data bottleneck phenomenon is more severe.

The manufacturing competitiveness of DRAMs in the 1Transistor-1Capacitor (1T-1C) structure has been maintained by lowering the unit cost of production per bit through miniaturization. To date, the most effective method to reduce the unit cost of production per bit is to reduce a minimum line width in a device design, such as Moore's Law or pitch scaling, thereby reducing the area of cells occupied per unit area to increase the memory capacity of a chip and at the same time, maximizing the number of chips that may be produced from a single wafer.

In addition to improving the degree of integration through the implementation of miniaturization of a minimum line width described above, the DRAM cell structure has improved the degree of integration through the optimization of a cell structure in a given minimum line width process, and research has been conducted on the structure of a cell transistor, the structure of a capacitor, and the structure of two transistor-zero capacitor (2T-0C) with an ultimate goal of implementing a memory cell in an area of 4F2.

### SUMMARY

The present disclosure provides a semiconductor device with reduced power consumption.

The present disclosure also provides a semiconductor device with an improved degree of integration and improved reliability.

Objects to be achieved by the present invention are not limited to the objects mentioned above, and other objects that are not mentioned above will be clearly understood by those skilled in the art from the following description.

An embodiment of the inventive concept provides a semiconductor device including a substrate, a first transistor on the substrate, an interlayer insulating layer covering the first transistor, a second transistor on the interlayer insulating layer, and a storage node contact passing through the interlayer insulating layer, and connecting any one of source/drain electrodes of the first transistor and a gate electrode of the second transistor, wherein a first channel pattern of the first transistor includes an n-type oxide transistor, and a second channel pattern of the second transistor includes an p-type oxide transistor.

In an embodiment of the inventive concept, a semiconductor device includes a substrate, a first gate electrode on the substrate, a first insulating layer on the first gate electrode, a first channel pattern and first and second source/drain electrodes on the first insulating layer, a first interlayer insulating layer on the first channel pattern and the first and second source/drain electrodes, a second gate electrode on the first interlayer insulating layer, a second insulating layer on the second gate electrode, a second channel pattern and third and fourth source/drain electrodes on the second insulating layer, and a storage node contact passing through the first interlayer insulating layer, and connecting the second source/drain electrode and the second gate electrode, wherein the first gate electrode and the second gate electrode vertically overlap each other, the first source/drain electrode and the third source/drain electrode vertically overlap each other, the second source/drain electrode and the fourth source/drain electrode vertically overlap each other, and the first channel pattern and the second channel pattern vertically overlap each other.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a circuit diagram of a semiconductor device according to an embodiment of the inventive concept;

FIG. 2 is a plan view of a semiconductor device according to an embodiment of the inventive concept;

FIG. 3 to FIG. 5 are cross-sectional views of a semiconductor device according to an embodiment of the inventive concept, which are taken along lines A-A′, B-B′, and C-C′ of FIG. 2, respectively;

FIG. 6 is a plan view of a semiconductor device according to an embodiment of the inventive concept;

FIG. 7 to FIG. 9 are cross-sectional views of a semiconductor device according to an embodiment of the inventive concept, which are taken along lines A-A′, B-B′, and C-C′ of FIG. 6, respectively;

FIG. 10 to FIG. 15 are circuit diagrams for describing a method for operating a semiconductor device according to an embodiment of the inventive concept; and

FIG. 16 is a graph for describing a method for operating a semiconductor device according to an embodiment of the inventive concept.

### DETAILED DESCRIPTION

Hereinafter, a semiconductor device according to embodiments of the inventive concept and an operation method thereof will be described with reference to the accompanying drawings.

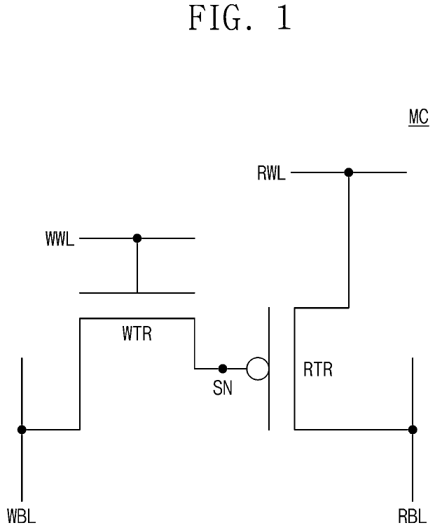

FIG. 1 is a circuit diagram of a semiconductor device according to an embodiment of the inventive concept.

Referring to FIG. 1, a unit memory cell MC may include a write transistor WTR and a read transistor RTR connected to the write transistor WTR. The write transistor WTR may be an n-type field effect transistor (FET), and the read transistor RTR may be a p-type FET. Although not illustrated, the semiconductor device may include a plurality of memory cells which are arranged two-dimensionally or three-dimensionally. A gate terminal of the write transistor WTR may be connected to a write word line WWL, and a drain terminal of the write transistor WTR may be connected to a write bit line WBL. Source/drain terminals of the read transistor RTR may be connected to a read word line RWL and a read bit line RBL, respectively. Although not illustrated, the read bit line RBL of the memory cell MC may be used as the write bit line WBL of a neighboring memory cell MC.

A source terminal of the write transistor WTR may be connected to a gate terminal of the read transistor RTR. The source terminal of the write transistor WTR may be named a storage node SN. The storage node SN may function as a gate of the read transistor RTR. The storage node SN may serve to store charges.

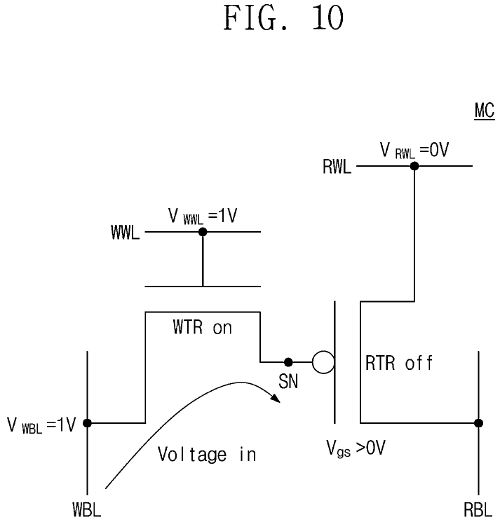

A program operation of the memory cell MC may be performed, for example, by applying a voltage to the write word line WWL and the write bit line WBL to turn on the write transistor WTR, and transferring an electrical signal (charge or data) to the storage node SN. Accordingly, an electrical signal transferred from the write bit line WBL may be stored in the storage node SN or in a gate insulating layer (not shown) of the read transistor RTR, and as a result, a threshold voltage of the read transistor RTR may be changed. A read operation of the memory cell MC may be performed, for example, by turning off the write transistor WTR, and applying a read voltage to the read word line RWL. The electrical signal stored in the storage node SN may be read through a current flowing through the read transistor RTR. A detailed operation method will be described later with reference to FIG. 10 to FIG. 16

The semiconductor device including the memory cell MC may also be named a two transistor-zero capacitor (2T-0C) memory device.

The semiconductor device according to an embodiment of the inventive concept may not include a separate capacitor for storing charges. Therefore, the area required for forming the capacitor may be reduced, which may improve the degree of integration of the semiconductor device.

In the semiconductor device according to an embodiment of the inventive concept, the read transistor RTR serves as a capacitor, so that a capacitor may be omitted, and thus, a pre-charge process may be omitted. Accordingly, effective retention time may be increased, and the frequency of a refresh operation may be reduced, which may decrease power consumption of the semiconductor device.

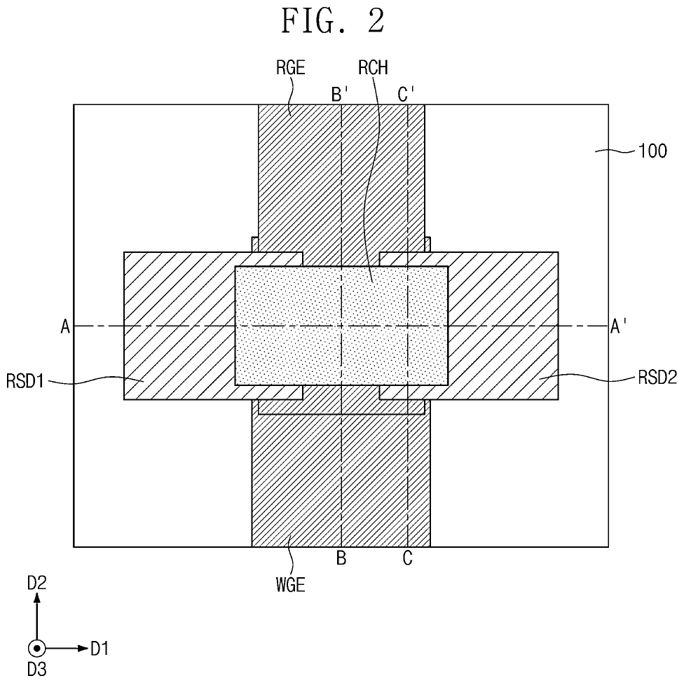

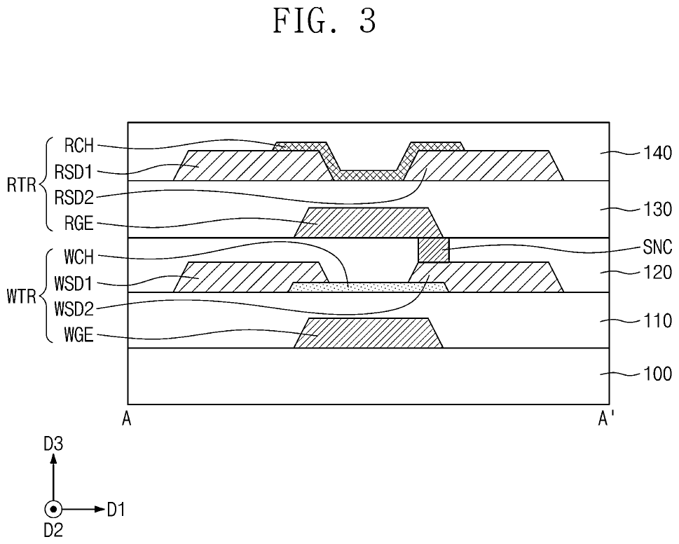

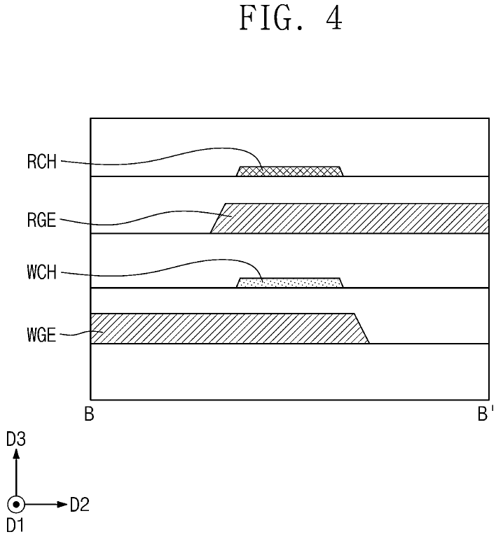

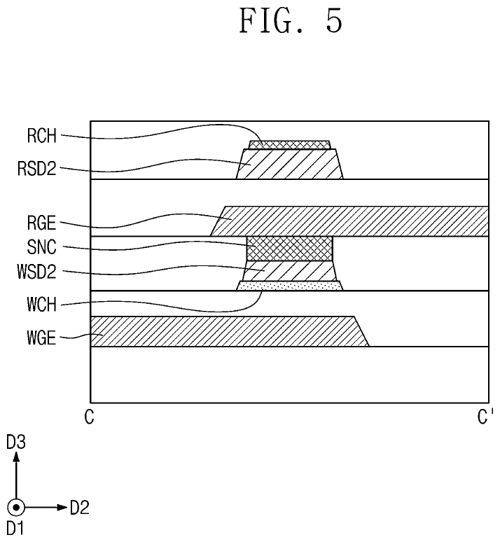

FIG. 2 is a plan view of a semiconductor device according to an embodiment of the inventive concept. FIG. 3 to FIG. 5 are cross-sectional views of a semiconductor device according to an embodiment of the inventive concept, which are taken along lines A-A′, B-B′, and C-C′ of FIG. 2, respectively.

Referring to FIG. 2 to FIG. 5, a semiconductor device according to an embodiment of the inventive concept may include a substrate 100.

The substrate 100 may be a semiconductor substrate. For example, the substrate 100 may be a silicon substrate, a flexible substrate, or a glass substrate.

A write transistor WTR may be provided on the substrate 100. The write transistor WTR may include a write gate electrode WGE, a first insulating layer 110, a write channel pattern WCH, and first and second write source/drain electrodes WSD1 and WSD2. As an example, the write transistor WTR may be an n-type transistor.

The write gate electrode WGE may be provided on the substrate 100. The write gate electrode WGE may extend in a second direction D2. When viewed in a plan perspective, the write gate electrode WGE may have a bar shape extending in the second direction D2. In the present specification, the first direction D1 and the second direction D2 may be directions parallel to an upper surface of the substrate 100 and intersecting each other. As an example, the write gate electrode WGE may include a metal material. As an example, the write gate electrode WGE may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), indium tin oxide (ITO), or combinations thereof.

Although not illustrated, the write gate electrode WGE may correspond to a write word line (WWL of FIG. 1), or may be connected to the write word line (WWL of FIG. 1).

The first insulating layer 110 which covers the write gate electrode WGE may be provided. The first insulating layer 110 may cover the substrate 100 and the write gate electrode WGE. As an example, the first insulating layer 110 may include at least one of silicon oxide, silicon nitride, aluminum oxide, zirconium oxide, or hafnium oxide.

The write channel pattern WCH and the first and second write source/drain electrodes WSD1 and WSD2 may be provided on the first insulating layer 110.

The write channel pattern WCH may be formed through a deposition process, and an upper surface of the write channel pattern WCH may be parallel to the upper surface of the substrate 100.

The write channel pattern WCH may include an n-type oxide semiconductor. As an example, the write channel pattern WCH may include at least one of indium (In), zinc (Zn), oxide (O), gallium (Ga), tin (Sn), or combinations thereof. As an example, the write channel pattern WCH may be any one of indium gallium zinc oxide (IGZO), indium gallium oxide (IGO), indium zinc tin oxide (IZTO), and indium tin oxide (ITO).

The first and second write source/drain electrodes WSD1 and WSD2 may be provided on the write channel pattern WCH and the first insulating layer 110. The first and second write source/drain electrodes WSD1 and WSD2 may be spaced apart from each other in the first direction D1. The first and second write source/drain electrodes WSD1 and WSD2 may cover both side surfaces of the write channel pattern WCH. As the first and second write source/drain electrodes WSD1 and WSD2 move away from the substrate 100 in a third direction perpendicular to the substrate 100, the length of the first and second write source/drain electrodes WSD1 and WSD2 in the first direction D1 and the second direction D2 may decrease. In other words, as the first and second write source/drain electrodes WSD1 and WSD2 move closer to the substrate 100, the area of cross-sections of the first and second write source/drain electrodes WSD1 and WSD2 cut in the first direction D1 and the second direction D2 may increase.

In other words, the write channel pattern WCH may be provided between the first insulating layer 110 and the first and second write source/drain electrodes WSD1 and WSD2 and between the first and second write source/drain electrodes WSD1 and WSD2, and may be deposited to a substantially uniform thickness. An upper surface of the write channel pattern WCH may be positioned at a lower level than upper surfaces of the first and second write source/drain electrodes WSD1 and WSD2.

The first and second write source/drain electrodes WSD1 and WSD2 may be formed through a deposition process. As an example, one of physical vapor deposition (PVD), PVD sputtering, chemical vapor deposition (CVD), or atomic layer deposition (ALD) may be used for the deposition of the first and second write source/drain electrodes WSD1 and WSD2.

The first and second write source/drain electrodes WSD1 and WSD2 may include a metal material. As an example, the first and second write source/drain electrodes WSD1 and WSD2 may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), indium tin oxide (ITO), or combinations thereof.

Although not illustrated, the first write source/drain electrode WSD1 may correspond to a write bit line (WBL of FIG. 1), or may be connected to the write bit line (WBL of FIG. 1).

A first interlayer insulating layer 120 which covers the write channel pattern WCH and the first and second write source/drain electrodes WSD1 and WSD2 may be provided. The first interlayer insulating layer 120 may be formed through a deposition process, and an upper surface of the first interlayer insulating layer 120 may be parallel to the upper surface of the substrate 100. The first interlayer insulating layer 120 may include at least one of silicon oxide, silicon nitride, aluminum oxide, zirconium oxide, or hafnium oxide.

A read transistor RTR may be provided on the first interlayer insulating layer 120. The read transistor RTR may include a read gate electrode RGE, a second insulating layer 130, a read channel pattern RCH, and first and second read source/drain electrodes RSD1 and RSD2. As an example, the read transistor RTR may be a p-type transistor.

The read gate electrode RGE may be provided on the first interlayer insulating layer 120. The read gate electrode RGE may extend in the second direction D2. When viewed in a plan perspective, the read gate electrode RGE may have a bar shape extending in the second direction D2. As an example, the read gate electrode RGE may include a metal material. As an example, the read gate electrode RGE may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), indium tin oxide (ITO), or combinations thereof.

A storage node contact SNC passing through the first interlayer insulating layer 120, and connecting the read gate electrode RGE and the second write source/drain electrode WSD2 may be provided. An upper surface of the storage node contact SNC may be in contact with a lower surface of the read gate electrode RGE, and a lower surface of the storage node contact SNC may be in contact with an upper surface of the second write source/drain electrode WSD2. The storage node contact SNC may be connected to the read gate electrode RGE to transfer a signal to the read gate electrode RGE according to a signal input to the second write source/drain electrode WSD2. That is, the operation of the read transistor RTR may be controlled by inputting a specific signal to the write transistor WTR by using the storage node contact SNC.

The storage node contact SNC may vertically overlap the write channel pattern WCH and the read channel pattern RCH.

The storage node contact SNC may include a metal material. As an example, the storage node contact SNC may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), indium tin oxide (ITO), or combinations thereof.

Although not illustrated, the storage node contact SNC may correspond to a storage node (SN of FIG. 1) which connects a source/drain electrode of the write transistor WTR and a gate electrode of the read transistor RTR.

The second insulating layer 130 which covers the read gate electrode RGE may be provided. The second insulating layer 130 may cover the first interlayer insulating layer 120 and the write gate electrode WGE. As an example, the second insulating layer 130 may include at least one of silicon oxide, silicon nitride, aluminum oxide, zirconium oxide, or hafnium oxide.

The read channel pattern RCH and the first and second read source/drain electrodes RSD1 and RSD2 may be provided on the second insulating layer 130.

The first and second read source/drain electrodes RSD1 and RSD2 may be formed on the second insulating layer 130 through a deposition process. One of physical vapor deposition (PVD), PVD sputtering, chemical vapor deposition (CVD), or atomic layer deposition (ALD) may be used for the deposition of the first and second read source/drain electrodes RSD1 and RSD2.

The first and second read source/drain electrodes RSD1 and RSD2 may be spaced apart from each other in the first direction D1. As the first and second read source/drain electrodes RSD1 and RSD2 move away from the second insulating layer 130 in a third direction, the length of the first and second read source/drain electrodes RSD1 and RSD2 in the first direction D1 and the second direction D2 may decrease. In other words, as the first and second read source/drain electrodes RSD1 and RSD2 move closer to the second insulating layer 130, the area of cross-sections of the first and second read source/drain electrodes RSD1 and RSD2 cut in the first direction D1 and the second direction D2 may increase.

The first and second read source/drain electrodes RSD1 and RSD2 may include a metal material. As an example, the first and second read source/drain electrodes RSD1 and RSD2 may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), indium tin oxide (ITO), or combinations thereof.

Although not illustrated, the first read source/drain electrode RSD1 may correspond to a read bit line (RBL of FIG. 1), or may be connected to the read bit line (RBL of FIG. 1), and the second read source/drain electrode RSD2 may correspond to a read word line (RWL of FIG. 1), or may be connected to the read word line (RWL of FIG. 1).

The read channel pattern RCH may be provided on the second insulating layer 130 and the first and second read source/drain electrodes RSD1 and RSD2. The read channel pattern RCH may cover a second insulating layer between the first and second read source/drain electrodes RSD1 and RSD2, a side surface of each of the first and second read source/drain electrodes RSD1 and RSD2, and portions of upper surfaces of the first and second read source/drain electrodes RSD1 and RSD2. The read channel pattern RCH may be deposited to a substantially uniform thickness.

The read channel pattern RCH may be formed through a deposition process. One of physical vapor deposition (PVD), PVD sputtering, chemical vapor deposition (CVD), or atomic layer deposition (ALD) may be used for the deposition of the read channel pattern RCH.

The read channel pattern RCH may include a p-type oxide semiconductor. As an example, the read channel pattern RCH may include a chalcogenide material. As an example, the read channel pattern RCH may include either selenium (Se) and tellurium (Te).

The read channel pattern RCH may vertically overlap the write channel pattern WCH.

A second interlayer insulating layer 140 which covers the read channel pattern RCH and the first and second read source/drain electrodes RSD1 and RSD2 may be provided. The second interlayer insulating layer 140 may be formed through a deposition process, and an upper surface of the second interlayer insulating layer 140 may be parallel to the upper surface of the substrate 100. The second interlayer insulating layer 140 may include either silicon oxide or silicon nitride.

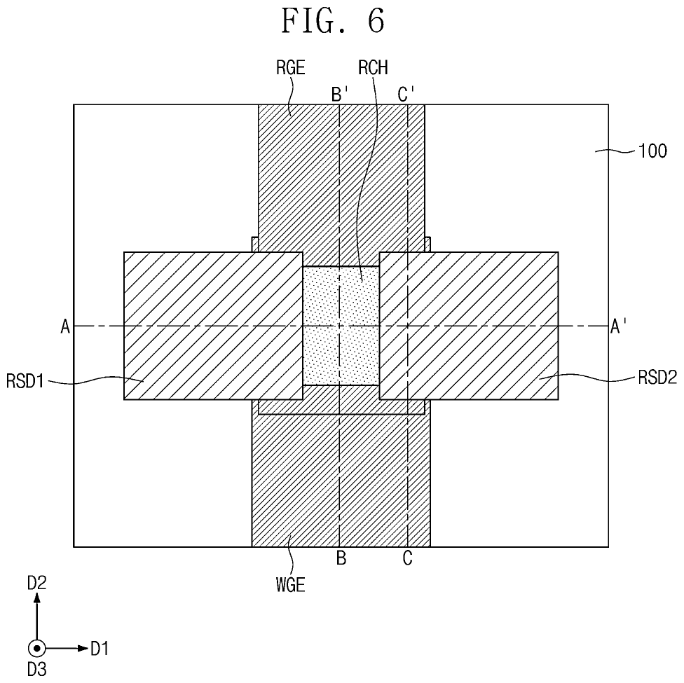

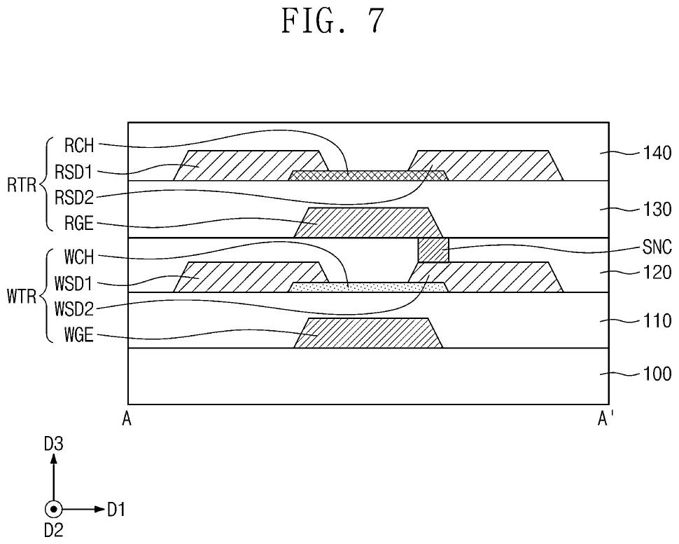

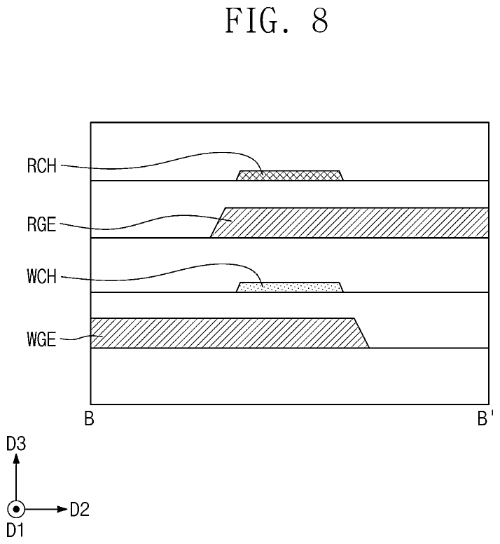

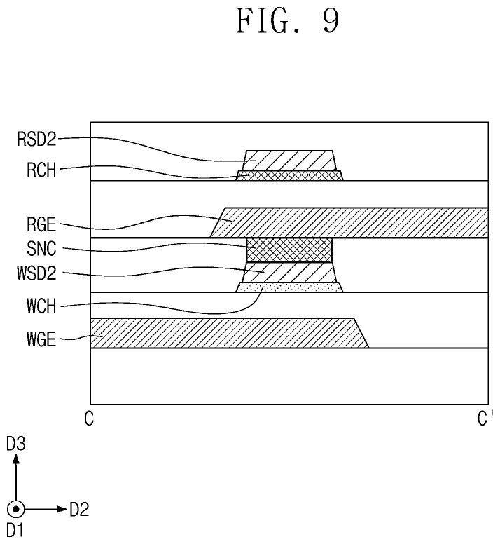

FIG. 6 is a plan view of a semiconductor device according to an embodiment of the inventive concept. FIG. 7 to FIG. 9 are cross-sectional views of a semiconductor device according to an embodiment of the inventive concept, which are taken along lines A-A′, B-B′, and C-C′ of FIG. 6, respectively. For concise description, detailed descriptions of components which are the same as or similar to those described above may be omitted.

Referring to FIG. 6 to FIG. 9, unlike the previous embodiment, a read channel pattern RCH may be deposited on a second insulating layer 130 before first and second read source/drain electrodes RSD1 and RSD2 are deposited. The read channel pattern RCH may be provided between the second insulating layer 130 and the first and second read source/drain electrodes RSD1 and RSD2 and between the first and second read source/drain electrodes RSD1 and RSD2, and may be deposited to a substantially uniform thickness. An upper surface of the read channel pattern RCH may be parallel to an upper surface of a substrate 100.

The first and second read source/drain electrodes RSD1 and RSD2 may be provided on the second insulating layer 130 and the read channel pattern RCH. The first and second read source/drain electrodes RSD1 and RSD2 may be spaced apart from each other in the first direction D1. The first and second read source/drain electrodes RSD1 and RSD2 may cover both side surfaces of the read channel pattern RCH.

An upper surface of the read channel pattern RCH may be positioned at a lower level than upper surfaces of the first and second read source/drain electrodes RSD1 and RSD2.

FIG. 10 to FIG. 15 are circuit diagrams for describing a method for operating a semiconductor device according to an embodiment of the inventive concept.

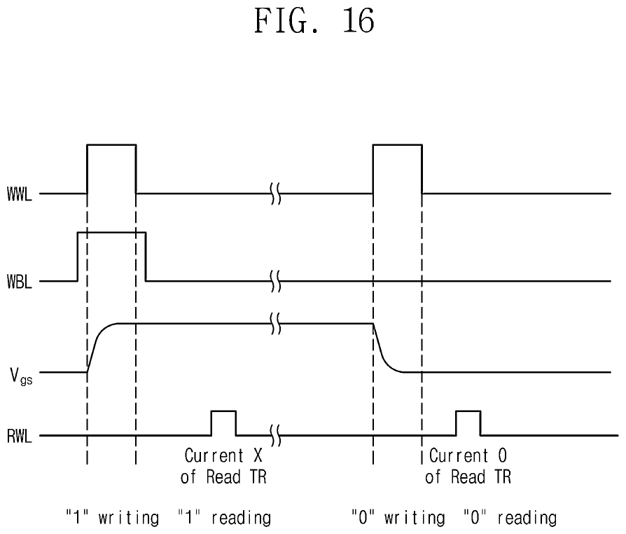

Referring to FIG. 10 and FIG. 16, for example, when data 1 is programmed into a memory cell MC, a turn-on voltage (e.g., 1 V) is applied to a write word line WWL to turn on a write transistor WTR. In this state, a program voltage (e.g., 1 V) may be applied to a write bit line WBL to store the data 1 on the storage node SN connected to a source electrode (not shown) of the write transistor WTR. The write transistor WTR may be an n-type FET, and accordingly, during the program operation, electrons may move from the source electrode (not shown) connected to the storage node SN to a drain electrode (not shown) connected to the write bit line WBL, and a current may flow in the opposite direction. Accordingly, the storage node SN may have a positive voltage value during the program operation. A read transistor RTR may be a p-type FET, and accordingly, during the program operation, a read gate electrode (not shown) connected to the storage node SN may have a positive voltage, so that the read transistor RTR, which is a p-type FET, may be turned off. A voltage may not be applied or a turn-off voltage may be applied to a read word line RWL and a read bit line RBL.

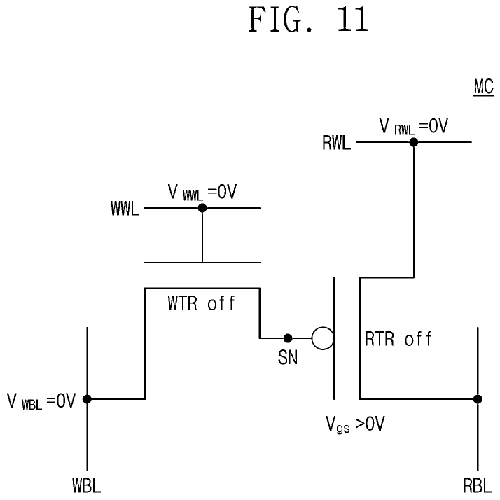

Referring to FIG. 11 and FIG. 16, in a process of subjecting the programmed data 1 to hold or standby, the storage node SN connected to a gate electrode (not shown) of the read transistor RTR has a positive voltage, and accordingly, the read transistor RTR, which is a p-type FET, may be turned off. As a result, even if noise is introduced into the read bit line RBL or there is a leaked current in a read gate insulating layer (not shown), a voltage value stored in the storage node SN or in a read gate insulating layer GI may maintain a positive value. Accordingly, if the voltage value stored in the storage node SN or in the read gate insulating layer GI is greater than a voltage of the read word line RWL which is applied to read the data 1 to be described later, the read transistor RTR may still remain in the turned-off state, thereby reducing the possibility of a read error, and reliability of the semiconductor device may be improved.

In the process of subjecting the programmed date to hold or standby, a turn-off voltage may be applied to the write word line WWL to reduce data leakage at the storage node SN.

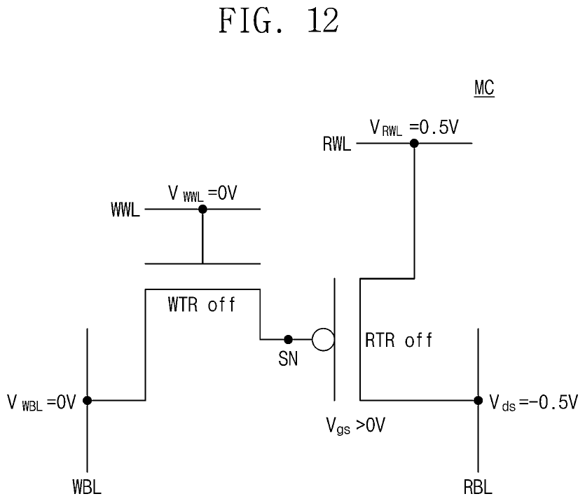

Referring to FIG. 12 and FIG. 16, for example, in order to read the data 1 stored in the memory cell MC, a turn-off voltage may be applied to the write word line WWL, a voltage of 0 V may be applied to the write bit line WBL, and a read voltage (e.g., 0.5 V) may be applied to the read word line RWL. Accordingly, a voltage V_{gs} of a gate electrode of the read transistor RTR with respect to a source electrode thereof may be 0.5 V, and a voltage V_{ds} of a drain electrode thereof with respect to the source electrode may be −0.5 V. Accordingly, the positive gate voltage V_{gs} is applied to the read transistor RTR, which is a p-type FET, so that the read transistor RTR may remain in the turned-off state, and a current value of the read bit line RBL recognizes a state corresponding to a turn-off current of the read transistor RTR as that the data 1 is programmed, so that the stored data may be read.

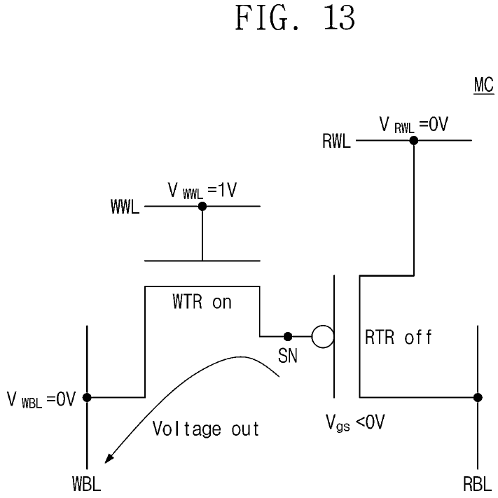

Referring to FIG. 13 and FIG. 16, for example, in order to program data 0 into the memory cell MC, a turn-on voltage (e.g., 1 V) is applied to the write word line WWL to turn on the write transistor WTR. In this state, a turn-off voltage (e.g., 0 V) may be applied to the write bit line WBL to program the data 0 into the storage node SN connected to a source electrode (not shown) of the write transistor WTR. The write transistor WTR may be an n-type FET, and accordingly, when programming the data 0, electrons may move from a drain electrode (not shown) connected to the write bit line WBL to a source electrode (not shown) connected to the storage node SN, and a current may flow in the opposite direction. Accordingly, the storage node SN may have a negative voltage value when programming the data 0. The read transistor RTR may be a p-type FET, and accordingly, when programming the data 0, a read gate electrode (not shown) connected to the storage node SN may have a negative voltage. However, a voltage may not be applied or a turn-off voltage may be applied to the read word line RWL to control the read transistor RTR not to operate. In the process of programming the data 0, a voltage may not be applied or a turn-off voltage may be applied to the read bit line RBL.

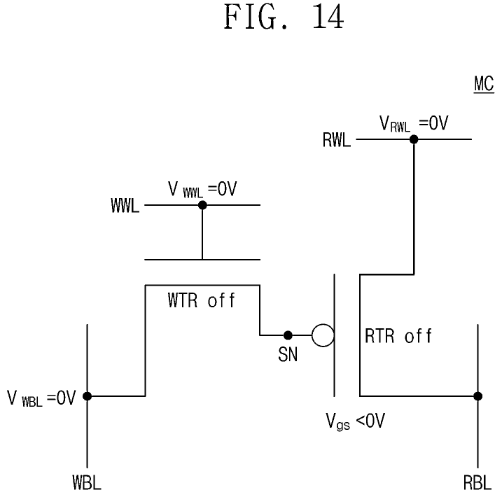

Referring to FIG. 14 and FIG. 16, in a process of subjecting the data 0 to hold or standby, a voltage may not be applied or a turn-off voltage may be applied to the read word line RWL, and accordingly, the read transistor RTR may be turned off.

In the process of subjecting the data 0 to hold, a voltage may not be applied or a turn-off voltage may be applied to the write word line WWL and the write bit line WBL to prevent data stored in the storage node SN from being changed.

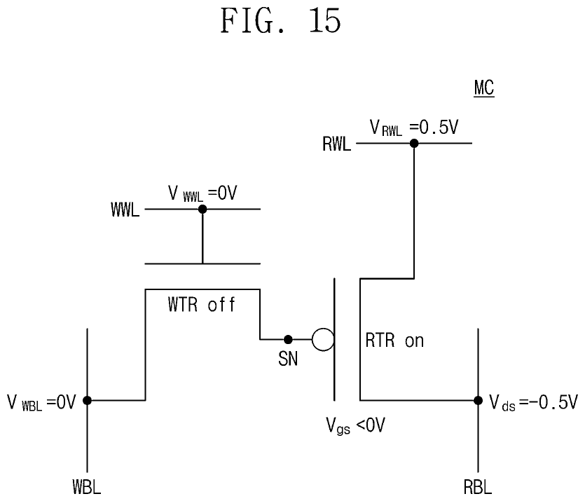

Referring to FIG. 15 and FIG. 16, for example, in order to read the data 0 stored in the memory cell MC, a voltage may not be applied or a turn-off voltage may be applied to the write word line WWL and the write bit line WBL, and a read voltage (e.g., 0.5 V) may be applied to the read word line RWL. Accordingly, the voltage V_{gs} of a gate electrode of the read transistor RTR with respect to a source electrode thereof may be −0.5 V, and the voltage V_{ds} of a drain electrode thereof with respect to the source electrode may be −0.5 V. Accordingly, the negative gate voltage V_{gs} is applied to the read transistor RTR, which is a p-type FET, so that the read transistor RTR may be turned on, and a current is sensed from the read bit line RBL, so that the data 0 may be read.

A semiconductor device according to the inventive concept replaces a capacitor with a read transistor, so that a pre-charge process may be omitted, and accordingly, effective retention time may be increased, the frequency of a refresh operation may be reduced, and power consumption of the semiconductor device may be decreased.

A semiconductor device according to the inventive concept replaces a capacitor with a p-type read transistor, and thus, may be resistant to noise in a process of maintaining a programmed electrical signal, and accordingly, the possibility of a read error is reduced, which may improve the reliability of the semiconductor device.

A semiconductor device according to the inventive concept does not include a capacitor, so that the area occupied by the semiconductor device may be reduced, and accordingly, the degree of integration of the semiconductor device may be improved.

Although the present invention has been described with reference to the accompanying drawings, it will be understood by those having ordinary skill in the art to which the present invention pertains that various changes in form and details may be made therein without departing from the spirit and scope of the present invention. Therefore, it is to be understood that the above-described embodiments are exemplary and non-limiting in every respect.

What is claimed is:

1. A semiconductor device comprising:
a substrate;
a first transistor on the substrate;
an interlayer insulating layer covering the first transistor;
a second transistor on the interlayer insulating layer; and
a storage node contact passing through the interlayer insulating layer, and connecting any one of source/drain electrodes of the first transistor and a gate electrode of the second transistor,
wherein:
a first channel pattern of the first transistor includes an n-type oxide transistor; and
a second channel pattern of the second transistor includes an p-type oxide transistor.

2. The semiconductor device of claim 1, wherein the first channel pattern and the second channel pattern vertically overlap each other.

3. The semiconductor device of claim 1, wherein the first transistor comprises a first gate electrode on the substrate, a first insulating layer on the first gate electrode, the first channel pattern on the first insulating layer, and first and second source/drain electrodes, wherein the first and second source/drain electrodes are spaced apart in a first direction parallel to the substrate.

4. The semiconductor device of claim 1, wherein the second transistor comprises a second gate electrode on the interlayer insulating layer, a second insulating layer on the second gate electrode, the second channel pattern on the second insulating layer, and third and fourth source/drain electrodes, wherein the third and fourth source/drain electrodes are spaced apart in the first direction.

5. The semiconductor device of claim 1, wherein the first gate electrode of the first transistor and the second gate electrode of the second transistor extend in a second direction parallel to the substrate and vertically crossing the first direction.

6. The semiconductor device of claim 2, wherein the first and second source/drain electrodes are disposed on the first channel pattern and the first insulating layer.

7. The semiconductor device of claim 3, wherein the second channel pattern is disposed on the third and fourth source/drain electrodes and the second insulating layer.

8. The semiconductor device of claim 7, wherein the thickness of the second channel pattern is substantially uniform.

9. The semiconductor device of claim 3, wherein the third and fourth source/drain electrodes are disposed on the second channel pattern and the second insulating layer.

10. The semiconductor device of claim 1, wherein the storage node contact vertically overlaps the first channel pattern and the second channel pattern.

11. The semiconductor device of claim 1, wherein the second channel pattern comprises a chalcogenide material.

12. A semiconductor device comprising:
a substrate;
a first gate electrode on the substrate;
a first insulating layer on the first gate electrode;
a first channel pattern and first and second source/drain electrodes on the first insulating layer;
a first interlayer insulating layer on the first channel pattern and the first and second source/drain electrodes;
a second gate electrode on the first interlayer insulating layer;
a second insulating layer on the second gate electrode;
a second channel pattern and third and fourth source/drain electrodes on the second insulating layer; and
a storage node contact passing through the first interlayer insulating layer, and connecting the second source/drain electrode and the second gate electrode,
wherein:
the first gate electrode and the second gate electrode vertically overlap each other;
the first source/drain electrode and the third source/drain electrode vertically overlap each other;
the second source/drain electrode and the fourth source/drain electrode vertically overlap each other; and
the first channel pattern and the second channel pattern vertically overlap each other.

13. The semiconductor device of claim 12, wherein:
the first channel pattern comprises an n-type oxide transistor; and
the second channel pattern comprises a p-type oxide transistor.

14. The semiconductor device of claim 13, wherein the second channel pattern comprises a chalcogenide material.

15. The semiconductor device of claim 12, wherein:
the first and second source/drain electrodes are spaced apart in a first direction parallel to the substrate; and
the third and fourth source/drain electrodes are spaced apart in the first direction.

16. The semiconductor device of claim 15, wherein the first and second source/drain electrodes are disposed on the first channel pattern and the first insulating layer.

17. The semiconductor device of claim 15, wherein the second channel pattern is disposed on the third and fourth source/drain electrodes and the second insulating layer.

18. The semiconductor device of claim 17, wherein the thickness of the second channel pattern is substantially uniform.

19. The semiconductor device of claim 15, wherein the third and fourth source/drain electrodes are disposed on the second channel pattern and the second insulating layer.

20. The semiconductor device of claim 12, further comprising a second interlayer insulating layer covering the third and fourth source/drain electrodes and the second channel pattern.
